(19) United States
(12) Patent Application Publication
(10) Pub. No.: US 2025/0374523 A1
(43) Pub. Date: Dec. 4, 2025

(54) SEMICONDUCTOR DEVICE AND METHOD OF MANUFACTURING THE SAME

(71) Applicant: SAMSUNG ELECTRONICS CO., LTD., SUWON-SI (KR)

(72) Inventor: Moonju HONG, Suwon-si (KR)

(21) Appl. No.: 18/982,239

(22) Filed: Dec. 16, 2024

(30) Foreign Application Priority Data
May 29, 2024 (KR) 10-2024-0069994

(51) Int. Cl. H10B 12/00

(52) U.S. Cl. CPC H10B 12/33; H10B 12/05

(57) ABSTRACT

A semiconductor device includes a bit line extending in a first direction parallel to an upper surface of the substrate. A first channel pattern is connected to the bit line. The first channel pattern extends perpendicular to the upper surface of the substrate. A gate insulating pattern is disposed on the first channel pattern. A word line is disposed on the gate insulating pattern and extends in a second direction that is parallel to the upper surface of the substrate and perpendicular to the first direction. Data storage patterns are spaced apart from each other in the first direction and the second direction. A landing pad is disposed on each of the data storage patterns. A second channel pattern is disposed on the landing pad. The second channel pattern extends from a first end of the first channel pattern in the first direction.

### CROSS-REFERENCE TO RELATED APPLICATION

This application claims priority under 35 U.S.C. § 119 to Korean Patent Application No. 10-2024-0069994, filed on May 29, 2024 in the Korean Intellectual Property Office, the disclosure of which is incorporated by reference in its entirety herein.

### 1. TECHNICAL FIELD

Embodiments of the present disclosure relate to a semiconductor device and a method of manufacturing the semiconductor device.

### 2. DISCUSSION OF RELATED ART

The technology concerning the manufacture of semiconductor devices is being developed to provide increased integration density, operation speeds, and yields of semiconductor devices. Research concerning a vertical channel transistor (VCT) is being conducted to increase the integration density, resistance, or current drive capability of a transistor. In the semiconductor device including the vertical channel transistor (VCT), a contact that connects a channel pattern and a landing pad LP may be formed.

### SUMMARY

One or more embodiments provide a semiconductor device with increased electrical characteristics and reliability.

According to an embodiment of the present disclosure, a semiconductor device includes a bit line extending in a first direction parallel to an upper surface of the substrate. A first channel pattern is connected to the bit line. The first channel pattern extends perpendicular to the upper surface of the substrate. A gate insulating pattern is disposed on the first channel pattern. A word line is disposed on the gate insulating pattern and extends in a second direction that is parallel to the upper surface of the substrate and perpendicular to the first direction. Data storage patterns are spaced apart from each other in the first direction and the second direction. A landing pad is disposed on each of the data storage patterns. A second channel pattern is disposed on the landing pad. The second channel pattern extends from a first end of the first channel pattern in the first direction.

According to embodiment of the present disclosure, a method of manufacturing a semiconductor device includes preparing a landing pad. The landing pad includes a data storage pattern disposed on a first surface of the landing pad and an insulating film coated on a second surface of the landing pad opposite to the first surface. An upper portion of the landing pad is exposed by removing the insulating film from the landing pad. A second channel pattern is formed on the exposed upper portion of the landing pad. The second channel pattern is coated with the insulating film and a planarization process is performed thereon. A mold portion is formed on a first insulating layer. The mold portion is disposed between the landing pad and a second landing pad. The mold portion extends in a direction perpendicular to the first insulating layer. A first channel pattern is formed on an outer side surface of the mold portion and an upper portion of the first channel pattern is opened. A gate insulating pattern is formed on a side surface of the first channel pattern. A word line is formed on a side surface of the gate insulating pattern. A bit line is formed on the first channel pattern.

According to an embodiment of the present disclosure, a semiconductor device includes a landing pad disposed in a first insulating layer. A data storage pattern is disposed under the landing pad. A mold portion extends in a vertical direction on the first insulating layer. A first channel pattern is disposed on an outer side surface of the mold portion and extends in a direction perpendicular to the landing pad. A second channel pattern extends horizontally on a top surface of the landing pad. A gate insulating pattern is disposed on a side surface of the first channel pattern. A word line is disposed on a side surface of the gate insulating pattern. A bit line is disposed on the first channel pattern. The bit line extends in a direction perpendicular to the word line. A silicon nitride in an upper end portion of the mold portion protrudes further upward than a top surface of the first channel pattern.

Additional aspects of embodiments of the present disclosure will be set forth in part in the description which follows and, in part, will be apparent from the description, or may be learned by practice of the present disclosure.

### BRIEF DESCRIPTION OF THE DRAWINGS

These and/or other aspects and features of the present disclosure will become apparent and more readily appreciated from the following description of non-limiting embodiments, taken in conjunction with the accompanying drawings of which:

FIG. 1 is a diagram schematically illustrating a semiconductor device according to an embodiment of the present disclosure;

FIG. 2 is a perspective view schematically illustrating a memory cell array of the semiconductor device of FIG. 1 according to an embodiment of the present disclosure;

FIG. 3 is a cross-sectional view illustrating an example of a semiconductor device according to an embodiment of the present disclosure;

FIGS. 4 to 11 are diagrams to describe a method of manufacturing the semiconductor device of FIG. 3 according to embodiments of the present disclosure;

FIG. 12 is a cross-sectional view illustrating another example of a semiconductor device according to an embodiment of the present disclosure;

FIGS. 13 to 19 are diagrams to describe a method of manufacturing the semiconductor device of FIG. 12 according to embodiments of the present disclosure;

FIG. 20 is a cross-sectional view illustrating another example of a semiconductor device according to an embodiment of the present disclosure; and

FIGS. 21 to 27 are diagrams to describe a method of manufacturing the semiconductor device of FIG. 20 according to embodiments of the present disclosure.

### DETAILED DESCRIPTION OF EMBODIMENTS

Hereinafter, non-limiting embodiments will be described in detail with reference to the accompanying drawings. When describing the non-limiting embodiments with reference to the accompanying drawings, like reference numerals refer to like components and a repeated description related thereto may be omitted for economy of explanation.

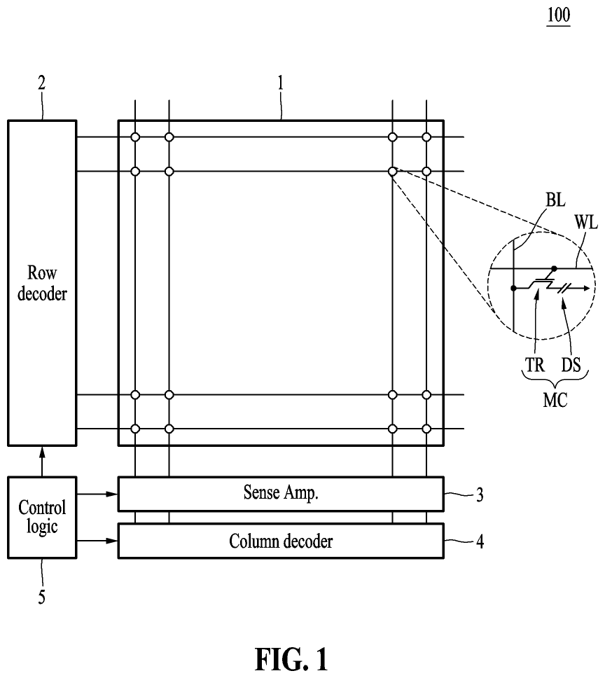

FIG. 1 is a diagram schematically illustrating a semiconductor device according to an embodiment.

A semiconductor device 100 of an embodiment shown in FIG. 1 may include a memory cell array 1, a row decoder 2, a sense amplifier 3, a column decoder 4, and a control logic 5. For example, in an embodiment the semiconductor device 100 may be a semiconductor memory device, and may be implemented as a dynamic random access memory (DRAM) device.

The memory cell array 1 may include a plurality of memory cells MC that are two-dimensionally or three-dimensionally arranged. For example, in an embodiment the memory cell array 1 may be disposed on one surface of a substrate, and a plane of the memory cell array 1 may be parallel to a plane of the substrate. Each of the memory cells MC may be connected to a word line WL and a bit line BL that cross each other.

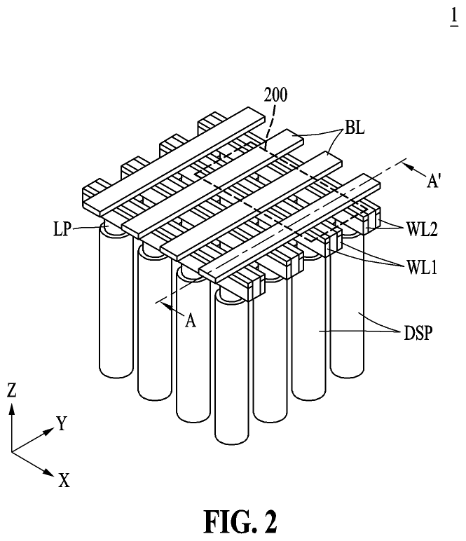

In an embodiment, each of the memory cells MC may include a selection element TR and a data storage element DS. The selection element TR and the data storage element DS may be electrically connected to each other. The selection element TR may be connected to both the word line WL and the bit line BL. For example, in an embodiment the selection element TR may be provided at a position in which the word line WL and the bit line BL cross each other. In an embodiment, the selection element TR may include, for example, a field effect transistor (FET). The data storage element DS may include, for example, a capacitor, a magnetic tunnel junction pattern, or a variable resistor. For example, the selection element TR may be a transistor, a gate electrode of the transistor may be connected to the word line WL, and a source terminal or a drain terminal of the transistor may be connected to (e.g., electrically connected thereto) the bit line BL or the data storage element DS. An example of a connection structure among the word line WL, the bit line BL, the selection element TR, and the data storage element DS of each of the memory cells MC in the memory cell array 1 will be described below with reference to FIG. 2.

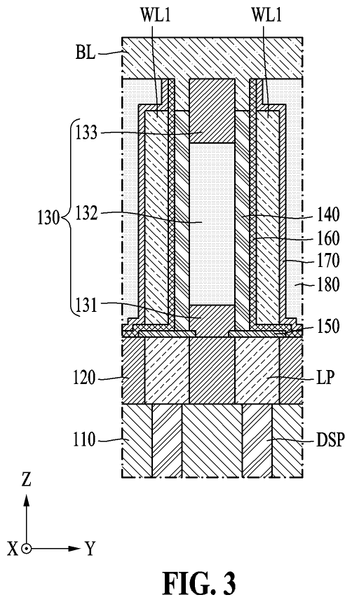

In an embodiment, a selection element TR of each of the memory cells MC may include a vertical channel transistor (VCT). In an embodiment, a lengthwise direction of a channel of the vertical channel transistor (VCT) may be perpendicular to one surface (e.g., a top surface) of the substrate. A data storage element DS of each of the memory cells MC may include a data storage pattern DSP. An example of a memory cell MC including a vertical channel transistor (VCT) will be described below with reference to FIG. 3.

The row decoder 2 may decode an address that is input from the outside of the semiconductor device 100 (e.g., input from an external device). The row decoder 2 may select one of word lines WL of the memory cell array 1, based on a result obtained by decoding the address. In an embodiment, the result (e.g., the decoded address) obtained by decoding the address in the row decoder 2 may be provided to a row driver. The row driver may separately provide predetermined voltages to the selected word line WL and unselected word lines, in response to controls of control circuits.

In an embodiment, the sense amplifier 3 may sense, amplify, and output a difference in voltage between a reference bit line and a bit line BL that is selected based on an address decoded by the column decoder 4.

The column decoder 4 may provide a data transmission path between the sense amplifier 3 and an external device (e.g., a memory controller). The column decoder 4 may decode an externally input address to select one of bit lines BL.

The control logic 5 may generate a control signal that is used to control an operation of writing or reading data to or from a corresponding memory cell in the memory cell array 1.

For reference, the row decoder 2, the sense amplifier 3, the column decoder 4, and the control logic 5 are illustrated around the memory cell array 1. However, embodiments of the present disclosure are not necessarily limited thereto. For example, a peripheral circuit including the row decoder 2, the sense amplifier 3, the column decoder 4, and the control logic 5 may be disposed on a plane different from a plane on which the memory cell array 1 is disposed. The peripheral circuit may be disposed above or below the memory cell array 1, using a cell over peripheral (COP) structure. In an embodiment, the peripheral circuit may be provided on the substrate, and the memory cell array 1 may be provided on the peripheral circuit. However, embodiments of the present disclosure are not necessarily limited thereto. For example, in an embodiment the peripheral circuit may be provided on a first substrate, and the memory cell array 1 may be provided on a second substrate. In this embodiment, the first substrate and the second substrate may face each other.

FIG. 2 is a perspective view schematically illustrating the memory cell array 1 of the semiconductor device 100 of FIG. 1.

FIG. 2 is a perspective view schematically illustrating the memory cell array 1 of FIG. 1, and illustrates a state in which a substrate including the data storage pattern DSP is vertically flipped on the landing pad LP. In an embodiment, to increase an integration density and performance of a semiconductor device, the semiconductor device may be manufactured by manufacturing a substrate through a back-end-of-line (BEOL) process, flipping the substrate, and forming a cell array on a landing pad LP.

Referring to FIG. 2, in an embodiment the semiconductor device 100 may include a data storage pattern DSP, a landing pad LP, word lines WL1 and WL2, and a bit line BL. The bit line BL may extend longitudinally in a first direction (e.g., a Y-axis direction). The word lines WL1 and WL2 may be disposed on the landing pad LP. The word lines WL1 and WL2 may extend in a second direction (e.g., an X-axis direction) perpendicular to the first direction. The first direction and the second direction may be parallel to a plane corresponding to the substrate or the memory cell array 1. For example, in an embodiment the first and second directions may be parallel to an upper surface of the substrate and may be perpendicular to each other or cross each other at another angle. For example, the substrate may have a shape of a plate extending along a plane defined by the first direction and the second direction. In an embodiment, a mold portion and a channel pattern may be formed on or above the landing pad LP.

Hereinafter, a portion 200 of the semiconductor device 100 according to an embodiment is mainly described in detail with reference to FIGS. 3 to 27. Components of the semiconductor device 100 that will be described below are examples to describe the technical idea of embodiments of the present disclosure, and the scope of embodiments of the present disclosure are not necessarily limited thereto.

FIG. 3 is a cross-sectional view illustrating an example of a semiconductor device according to an embodiment. FIG. 3 illustrates a cross section (e.g., a cross section corresponding to a YZ plane) obtained by cutting a memory cell of the semiconductor device in a direction perpendicular to a substrate along line A-A′ of FIG. 2. Line A-A′ may be parallel to a bit line BL.

In an embodiment, the semiconductor device 100 may include a landing pad LP, a data storage pattern DSP, a first insulating layer 120, a mold portion 130, a first channel pattern 140, a second channel pattern 150, a gate insulating pattern 160, a word line WL1, and the bit line BL.

The data storage pattern DSP may be disposed on one side (e.g., a lower portion in the Z-axis direction) of the landing pad LP. The data storage pattern DSP may be electrically connected to the first channel pattern 140 and the second channel pattern 150 through the landing pad LP. Data storage patterns DSP may be spaced apart in the first direction and the second direction. In an embodiment, the data storage patterns DSP may be arranged in a form of a matrix and may completely or partially overlap landing pads LP (e.g., in the Z-axis direction).

The data storage patterns DSP may be capacitors. In an embodiment, the data storage patterns DSP may include storage electrodes, a plate electrode, and capacitor dielectric films interposed between the storage electrodes and the plate electrode. The storage electrodes may be in direct contact with the landing pads LP. The storage electrodes may have various shapes, for example, a circular shape, an elliptical shape, a rectangular shape, a square shape, a rhombus shape, or a hexagonal shape.

The landing pad LP may be disposed on the data storage pattern DSP (e.g., disposed directly thereon in the Z-axis direction). The landing pad LP may be disposed between insulating layers (e.g., in a plan view). The landing pad LP may have various shapes, for example, a circular shape, an elliptical shape, a rectangular shape, a square shape, a rhombus shape, a hexagonal shape, or a polygonal shape with a predetermined thickness. In an embodiment, when viewed in a direction perpendicular to the substrate, insulating layers may be disposed in an inner region and an outer region defined by the landing pad LP. The landing pad LP may include a conductive material. In an embodiment, the conductive material may include, for example, at least one of doped polysilicon, a conductive metal nitride, a conductive metal silicon nitride, a metal carbonitride, a conductive metal silicide, a conductive metal oxide, a two-dimensional (2D) material, a metal, or a metal alloy.

The first insulating layer 120 may be disposed between landing pads LP (e.g., in a plan view). For example, in an embodiment the first insulating layer 120 may be disposed in an inner region of the landing pad LP, when viewed in the direction perpendicular to the substrate. For example, in an embodiment in which the landing pad LP is formed in a shape of a donut, the first insulating layer 120 may be provided in an inner region including a central point of the shape of the donut. In addition, the first insulating layer 120 may also be provided between the landing pad LP and another landing pad. For example, the first insulating layer 120 may be provided in an outer region of the landing pad LP with the shape of the donut. The first insulating layer 120 may include an insulating material.

The first channel pattern 140 may be connected to the bit line BL (e.g., directly connected thereto) and disposed perpendicular to the substrate, such as an upper surface of the substrate. For example, the first channel pattern 140 may extend longitudinally in a third direction (e.g., the Z-axis direction) perpendicular to the landing pad LP on an outer side surface of the mold portion 130.

The second channel pattern 150 may extend horizontally from one end (e.g., a first end) of the first channel pattern 140 (e.g., a lower end in the Z-axis direction) in the first direction and may be disposed on the landing pad LP (e.g., disposed directly thereon in the Z-axis direction). For example, the second channel pattern 150 may extend horizontally in a direction parallel to an upper surface of the substrate on a top surface of the landing pad LP. The second channel pattern 150 may cover the landing pad LP. For example, in an embodiment an area of the second channel pattern 150 may be greater than or equal to an area of the top surface of the landing pad LP.

According to an embodiment, the first channel pattern 140 and the second channel pattern 150 may include semiconductor oxides of the same type as or a different type from each other. In an embodiment, the semiconductor oxides may include any one or any combination of IGZO, InₓO, ZnₓO, SnₓO, InₓZn_{y}O, InₓSn_{y}Zn_{z}O, AlₓZn_{y}Sn_{z}O, YbₓGa_{y}Zn_{z}O, and HfₓIn_{y}Zn_{z}O. However, embodiments of the present disclosure are not necessarily limited thereto. For example, in an embodiment the first channel pattern 140 may be formed of an indium gallium zinc oxide (IGZO), and the second channel pattern 150 may be formed of an indium tin oxide (ITO). The semiconductor oxide may include high proportions of a portion of elements. For example, in an embodiment the IGZO may be a gallium (Ga)-rich IGZO, and at least one of the first channel pattern 140 or the second channel pattern 150 may be a Ga-rich IGZO.

The gate insulating pattern 160 may be disposed on (e.g., disposed directly thereon) the first channel pattern 140. The gate insulating pattern 160 may include an insulating material.

The word line WL1 may be disposed on (e.g., disposed directly thereon) the gate insulating pattern 160 and may extend longitudinally in the second direction (e.g., the X-axis direction).

In an embodiment, the second insulating layer 170 may be disposed on (e.g., disposed directly thereon) the gate insulating pattern 160 and an outer side surface of the word line WL1, and may be a silicon nitride.

In an embodiment, the third insulating layer 180 may be included in an inner space surrounding the second insulating layer 170, and may be a silicon oxide.

The bit line BL may extend longitudinally in the first direction parallel to the substrate. The bit line BL may be formed on (e.g., disposed directly thereon) the first channel pattern 140 in a direction (e.g., the first direction) perpendicular to the word line WL1.

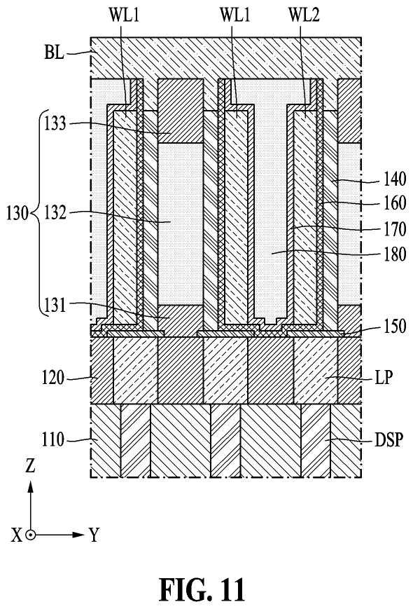

The mold portion 130 may protrude in the third direction (e.g., the Z-axis direction) perpendicular to one surface (e.g., a top surface in the Z-axis direction) of the first insulating layer 120. For example, in an embodiment the mold portion 130 may protrude further upward (e.g., in the Z-axis direction) than a top surface of the first channel pattern 140. The third direction may be perpendicular to the first direction and the second direction. The mold portion 130 may be disposed on (e.g., disposed directly on in the Z-axis direction) the first insulating layer 120 corresponding to a portion between landing pads LP. The mold portion 130 may extend longitudinally in the second direction and support the first channel pattern 140. In an embodiment, the mold portion 130 may include a silicon nitride 131, a silicon oxide 132, and a silicon nitride 133. The silicon oxide 132 may be disposed between the silicon nitrides 131 and 133 (e.g., in the Z-axis direction) to form the mold portion 130. For example, the silicon nitride 131 may be disposed in a lower end portion of the mold portion 130, the silicon nitride 133 may be disposed in an upper end portion of the mold portion 130, and the silicon oxide 132 may be disposed between the silicon nitrides 131 and 133 (e.g., in the Z-axis direction). The silicon nitride 133 in the upper end portion of the mold portion 130 may be disposed at a higher level than the first channel pattern 140. For reference, mold portions 130 may be arranged in the first direction (e.g., the Y-axis direction). For example, as illustrated in FIG. 11, the mold portions 130 may be spaced apart from each other in the first direction (e.g., the Y-axis direction).

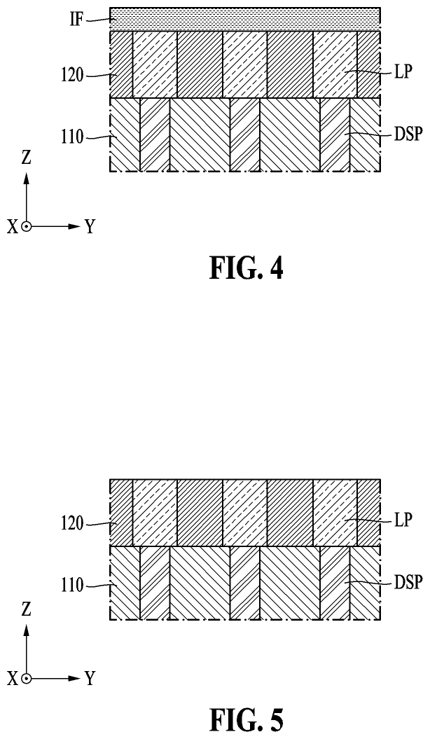

FIGS. 4 to 11 are diagrams to describe a method of manufacturing the semiconductor device of FIG. 3 according to embodiments of the present disclosure.

Referring to FIG. 4, a data storage pattern DSP may be disposed on one surface (e.g., a first surface) of a landing pad LP, and another surface (e.g., an opposite surface second surface) of the landing pad LP may be coated with an insulating film IF. For example, in an embodiment the data storage pattern DSP may be disposed on (e.g., disposed directly thereon) a lower surface of the landing pad LP in the Z-axis direction and the insulating film IF may be disposed on (e.g., disposed directly thereon) an upper surface of the landing pad LP in the Z-axis direction. In an embodiment, the landing pad LP may be disposed in the first insulating layer 120 and the data storage pattern DSP may be disposed on (e.g., disposed directly thereon) the landing pad LP. The data storage pattern DSP may be a capacitor CAP. The capacitor CAP may be connected to the landing pad LP, and a substrate may be prepared through a BEOL process. When the substrate is prepared, the substrate may be flipped such that the data storage pattern DSP on the landing pad LP may face downward.

Referring to FIG. 5, the insulating film IF on the landing pad LP may be removed so that an upper portion of the landing pad LP may be exposed and an upper portion of the first insulating layer 120 may be exposed. In an embodiment, the insulating film IF may be SiN. The insulating film IF may be completely removed by a chemical mechanical polishing (CMP) process.

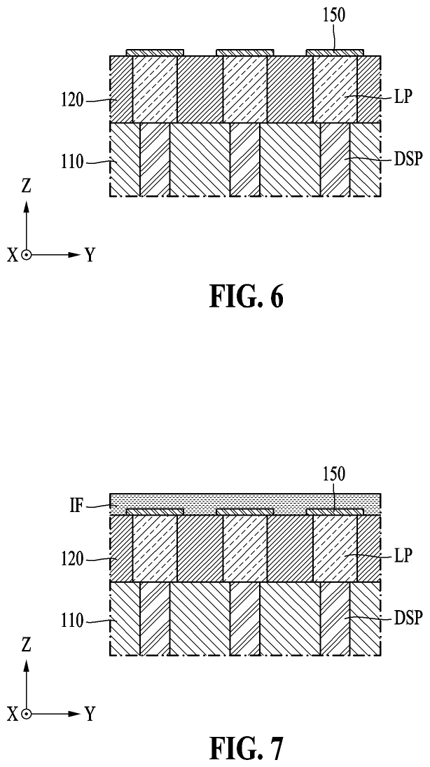

Referring to FIG. 6, the second channel pattern 150 may be formed on the portion of the landing pad LP (e.g., formed directly thereon in the Z-axis direction) that was exposed by removing the insulating film IF. In an embodiment, the second channel pattern 150 may cover the entire top surface of the landing pad LP. In an embodiment, the second channel pattern 150 may include a semiconductor oxide deposited by a physical vapor deposition (PVD) process, a chemical vapor deposition (CVD) process, or an atomic layer deposition (ALD) process. In an embodiment, the semiconductor oxide may include any one or any combination of two or more of IGZO, InₓO, ZnₓO, SnₓO, InₓZn_{y}O, InₓSn_{y}Zn_{z}O, AlₓZn_{y}Sn_{z}O, YbₓGa_{y}Zn_{z}O, and HfₓIn_{y}Zn_{z}O. However, embodiments of the present disclosure are not necessarily limited thereto. When the second channel pattern 150 is deposited, a top surface of the first insulating layer 120 may be exposed. For example, in an embodiment, a portion of a top surface of the first insulating layer 120 may be exposed by the second channel pattern 150 (e.g., a central portion) and the second channel pattern 150 may cover another portion of the top surface of the first insulating layer 120 (e.g., lateral ends thereof).

Referring to FIG. 7, the second channel pattern 150 and one surface (e.g., the top surface) of the first insulating layer 120 may be coated with an insulating film IF. In an embodiment, the insulating film IF may include at least one of a silicon nitride, a silicon oxide, or a silicon oxynitride. In an embodiment, a PVD process, a CVD process, or an ALD process may be used to coat the second channel pattern 150 and one surface (e.g., a first surface) of the first insulating layer 120 with the insulating film IF. In an embodiment, the second channel pattern 150 and the top surface of the first insulating layer 120 coated with the insulating film IF may be planarized by a CMP process.

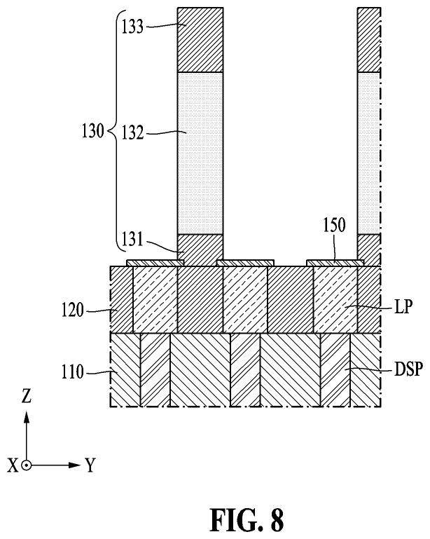

Referring to FIG. 8, an upper portion of the first insulating layer 120 may be exposed by an etching process. In an embodiment, the first insulating layer 120 may be a silicon nitride or a silicon oxide. The mold portion 130 may be formed on the exposed portion of the first insulating layer 120 to extend in a direction perpendicular to one surface (e.g., the top surface) of the first insulating layer 120 that is exposed. The mold portion 130 may include an insulating layer formed by the CVD process. In an embodiment, the mold portion 130 may include an insulating layer in which the silicon nitride 131, the silicon oxide 132, and the silicon nitride 133 are stacked (e.g., consecutively stacked in the Z-axis direction). In an embodiment, a silicon nitride may be at least one of a silicon carbonitride (SiCN), a silicon carbon oxynitride (SiCON), or silicon nitride (SiN). A silicon oxide may be one of hafnium oxide (HfO), aluminum oxide (AlO), and tantalum oxide (TaO).

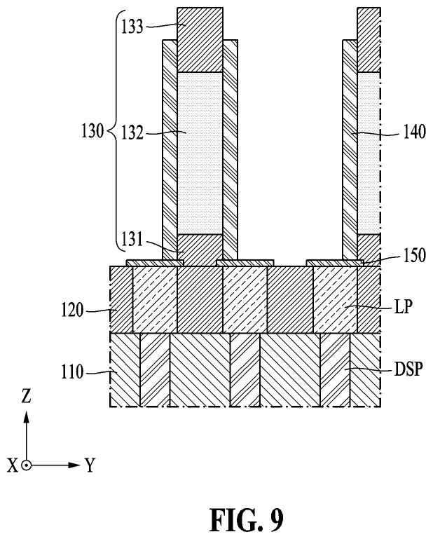

Referring to FIG. 9, in an embodiment the first channel pattern 140 may be formed on (e.g., formed directly thereon) the mold portion 130 by a PVD process, a CVD process, or an ALD process. In an embodiment, an upper portion of the first channel pattern 140 may be opened by an etch back process, to form a node.

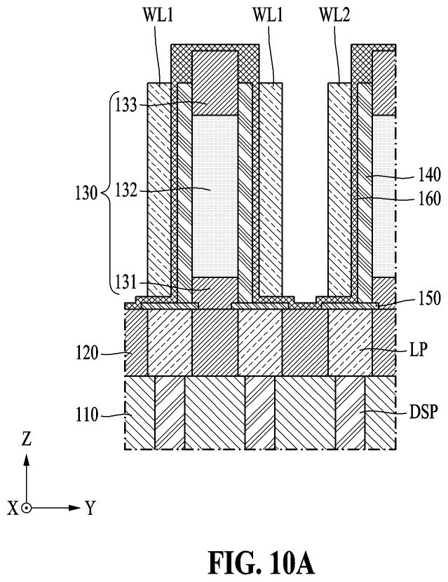

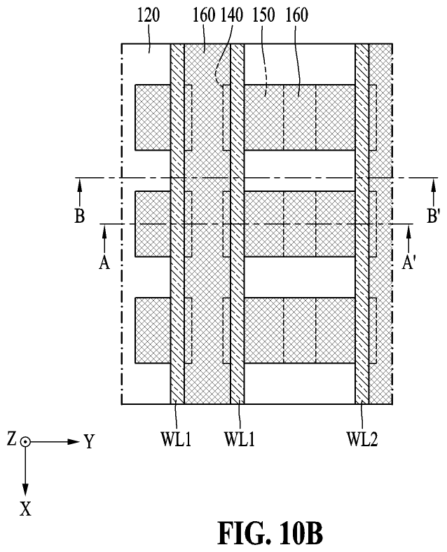

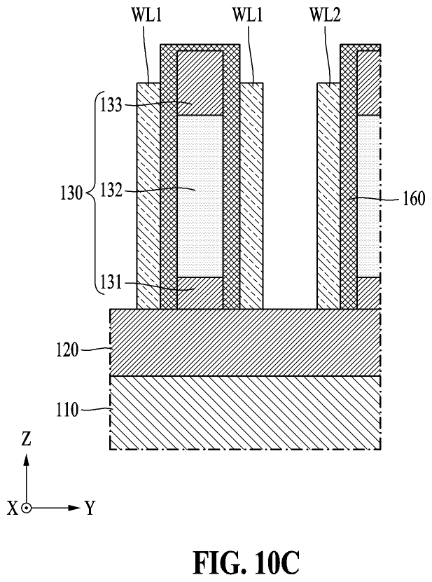

Referring to FIG. 10A, the gate insulating pattern 160 may conformally cover the first channel pattern 140. The word lines WL1 and WL2 may be formed on (e.g., formed directly thereon) the gate insulating pattern 160. The word lines WL1 and WL2 may include conductive materials. In an embodiment, chamfering of the word lines WL1 and WL2 may be performed by a wet etch process.

FIG. 10B illustrates a top surface of a portion (e.g., the portion 200 of FIG. 2) of the semiconductor device 100 including the word lines WL1 and WL2 formed as described above with reference to FIG. 10A. Line A-A′ is a line in a direction (e.g., the Y-axis direction) of a bit line BL of a region including a landing pad LP, and line B-B′ is a line in a direction of a region that does not include a landing pad LP. The mold portion 130 may extend longitudinally in the second direction (e.g., the X-axis direction).

FIG. 10C is a cross-sectional view taken along line B-B′ of FIG. 10B. FIG. 10C illustrates a lower insulating layer 110, the first insulating layer 120, the mold portion 130, and the word lines WL1 and WL2 formed on side surfaces of the mold portion 130. A thickness of the gate insulating pattern 160 illustrated in FIG. 10C may be greater than a thickness of the gate insulating pattern 160 illustrated in FIG. 10A. For example, the gate insulating pattern 160 illustrated in FIG. 10C may be thicker than the gate insulating pattern 160 illustrated in FIG. 10A, by a thickness of the first channel pattern 140.

Referring to FIG. 11, the bit line BL may be formed on (e.g., formed directly thereon) the mold portion 130 and the upper portion of the first channel pattern 140. The substrate on which the bit line BL is formed may be flipped again. In an embodiment, the flipped substrate may be coupled to a COP structure. However, embodiments of the present disclosure are not necessarily limited thereto. For example, in an embodiment the flipped substrate may be coupled to a lower COP structure of another substrate.

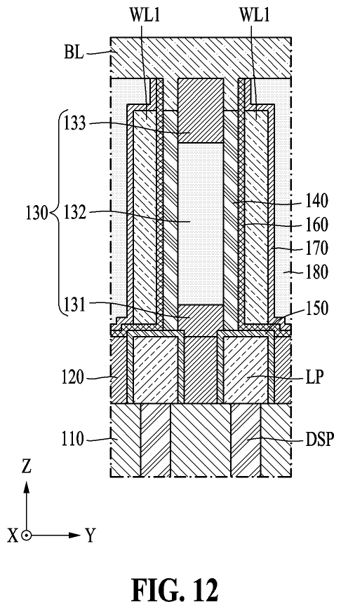

FIG. 12 is a cross-sectional view illustrating another example of a semiconductor device according to an embodiment.

A semiconductor device 100 of an embodiment of FIG. 12 may include a landing pad LP, a data storage pattern DSP disposed under the landing pad LP, a first insulating layer 120 disposed between landing pads LP, a mold portion 130 vertically extending on the first insulating layer 120, a first channel pattern 140 vertically disposed on an outer side surface of the mold portion 130, a second channel pattern 150 horizontally disposed on a top surface of the landing pad LP, a gate insulating pattern 160 disposed on a side surface of the first channel pattern 140, a word line WL1 disposed on a side surface of the gate insulating pattern 160, and a bit line BL formed in a direction perpendicular to the word line WL1 on the first channel pattern 140. In an embodiment, the second channel pattern 150 may extend longitudinally from the top surface of the landing pad LP to a side surface of the landing pad LP. For example, the second channel pattern 150 may cover opposing lateral side surfaces (e.g., in the Y-axis direction) of the landing pad LP. In an embodiment, the mold portion 130 may include a silicon nitride 131, a silicon oxide 132, and a silicon nitride 133 consecutively stacked in the Z-axis direction from a lower end portion thereof.

The second channel pattern 150 may be formed to extend from the top surface of the landing pad LP to the side surface of the landing pad LP. The landing pad LP may have various shapes, for example, a circular shape, an elliptical shape, a rectangular shape, a square shape, a rhombus shape, or a hexagonal shape. For example, in an embodiment in which the landing pad LP has a circular shape, the second channel pattern 150 may extend to a side surface of a rectangular shape surrounding the side surface of the landing pad LP. The second channel pattern 150 may be disposed on all surfaces other than a surface in direct contact with the data storage pattern DSP and the lower insulating layer 110. For example, the second channel pattern 150 may be disposed on the entire top surface and all side surfaces of the landing pad LP, or a portion of the top surface or side surfaces. For example, the second channel pattern 150 disposed on the entire top surface and side surfaces of the landing pad LP may have a shape of “II”, such as an inverted U-shape.

In an embodiment, the first channel pattern 140 and the second channel pattern 150 may be formed in an L-shape along the outer side surface of the mold portion 130 and the top surface of the landing pad LP. The first channel pattern 140 and the second channel pattern 150 with the L-shape may be integrally formed.

According to an embodiment, the second channel pattern 150 may include a semiconductor oxide of the same type as or a different type from the first channel pattern 140. In an embodiment, the semiconductor oxide may include any one or any combination of two or more of IGZO, InₓO, ZnₓO, SnₓO, InₓZn_{y}O, InₓSn_{y}Zn_{z}O, AlₓZn_{y}Sn_{z}O, YbₓGa_{y}Zn_{z}O, and HfₓIn_{y}Zn_{z}O. However, embodiments of the present disclosure are not necessarily limited thereto. For example, in an embodiment the first channel pattern 140 may be formed of an IGZO, and the second channel pattern 150 may be formed of an ITO. The semiconductor oxide may include high proportions of a portion of elements. For example, the IGZO may be a Ga-rich IGZO, and at least one of the first channel pattern 140 or the second channel pattern 150 may be a Ga-rich IGZO.

According to an embodiment, an area of the second channel pattern 150 may be greater than or equal to an area of the top surface of the landing pad LP.

A silicon nitride in an upper end portion of the mold portion 130 may be disposed at a higher level than the first channel pattern 140.

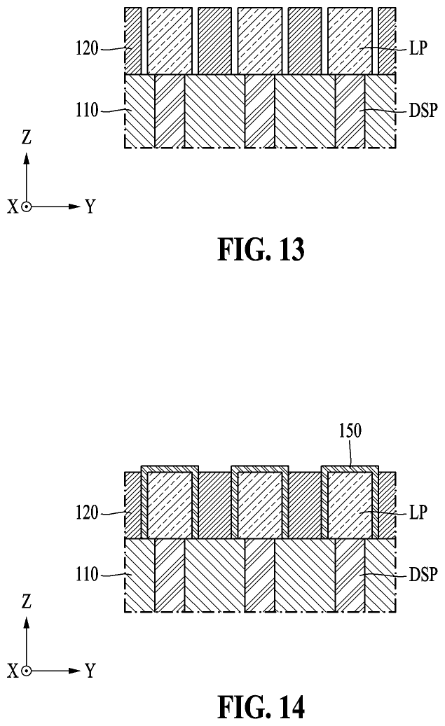

FIGS. 13 to 19 are diagrams to describe a method of manufacturing the semiconductor device 100 of FIG. 12 according to embodiments of the present disclosure.

As described above with reference to FIG. 4, the data storage pattern DSP may be disposed on one surface of the landing pad LP, and another surface of the landing pad LP may be coated with an insulating film IF. As described above with reference to FIG. 5, the insulating film IF on the landing pad LP may be removed, so that the top surface of the landing pad LP may be exposed.

Referring to FIG. 13, a portion of both sides of the first insulating layer 120 in direct contact with a side surface (e.g., lateral side surfaces) of the landing pad LP may be removed to form a recess. In an embodiment, the first insulating layer 120 may be SiN, and a portion of the first insulating layer 120 in direct contact with the side surface of the landing pad LP may be removed by an etching process.

Referring to FIG. 14, the second channel pattern 150 may be formed on the top surface and the side surface (e.g., a recess region of the first insulating layer 120) of the landing pad LP. The second channel pattern 150 may continuously cover at least the top surface and the side surface of the landing pad LP. In an embodiment, the second channel pattern 150 may include a semiconductor oxide deposited by a PVD process, a CVD process, or an ALD process. For example, in an embodiment the semiconductor oxide may include any one or any combination of two or more of IGZO, InₓO, ZnₓO, SnₓO, InₓZn_{y}O, InₓSn_{y}Zn_{z}O, AlₓZn_{y}Sn_{z}O, YbₓGa_{y}Zn_{z}O, and HfₓIn_{y}Zn_{z}O. However, embodiments of the present disclosure are not necessarily limited thereto.

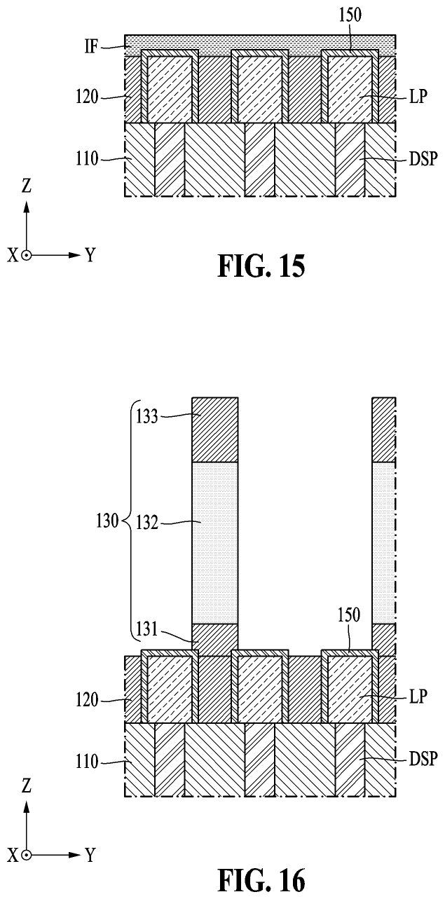

Referring to FIG. 15, the top surface of the landing pad LP on which the second channel pattern 150 is deposited may be coated with the insulating film IF. In an embodiment, when the top surface is coated with the insulating film IF, a planarization process may be performed using a CMP process.

Referring to FIG. 16, an upper portion of the first insulating layer 120 may be exposed. The mold portion 130 may be formed in a direction perpendicular to the substrate on the exposed upper portion of the first insulating layer 120 (e.g., the Z-axis direction). In an embodiment, the mold portion 130 may include the silicon nitride 131, the silicon oxide 132, and the silicon nitride 133 (e.g., consecutively stacked in the Z-axis direction).

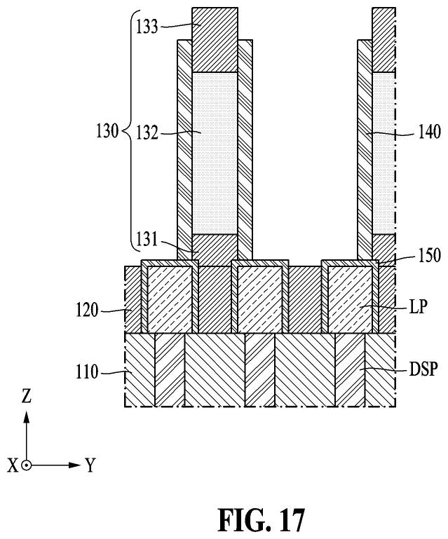

Referring to FIG. 17, in an embodiment the first channel pattern 140 may be formed on the mold portion 130 by a PVD process, a CVD process, or an ALD process. When the first channel pattern 140 is formed, an upper portion of the first channel pattern 140 may be opened by an etch back process, to form a node.

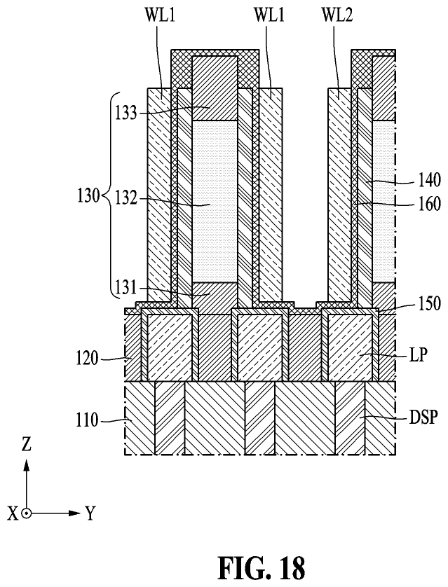

Referring to FIG. 18, the gate insulating pattern 160 may conformally cover the first channel pattern 140. The word lines WL1 and WL2 may be formed on (e.g., formed directly thereon) the gate insulating pattern 160. The word lines WL1 and WL2 may include conductive materials. In an embodiment, chamfering of the word lines WL1 and WL2 may be performed by a wet etch process.

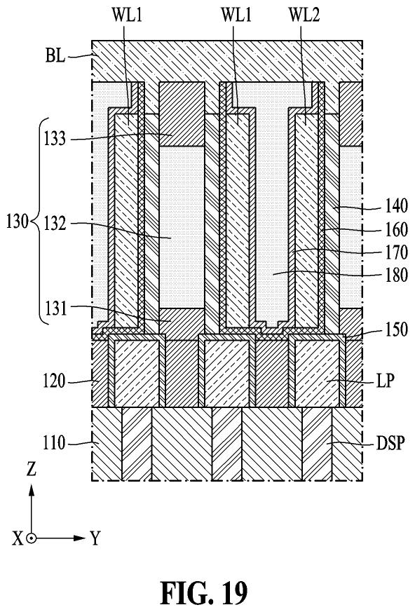

Referring to FIG. 19, the bit line BL may be formed on (e.g., formed directly thereon) the mold portion 130 and the first channel pattern 140.

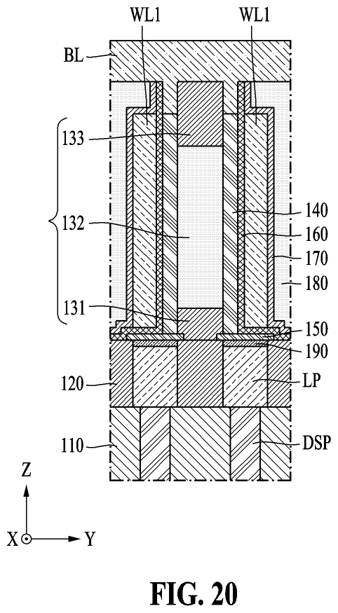

FIG. 20 is a cross-sectional view illustrating another example of a semiconductor device according to an embodiment.

In an embodiment, a semiconductor device 100 of FIG. 20 may include a landing pad LP, a data storage pattern DSP disposed under the landing pad LP, a first insulating layer 120 disposed between landing pads LP, a mold portion 130 vertically extending on the first insulating layer 120 (e.g., in the Z-axis direction), a first channel pattern 140 vertically disposed on an outer side surface of the mold portion 130, a second channel pattern 150 horizontally disposed on a top surface of the landing pad LP, a gate insulating pattern 160 disposed on a side surface of the first channel pattern 140, a word line WL1 disposed on a side surface of the gate insulating pattern 160, and a bit line BL formed in a direction perpendicular to the word line WL1 on the first channel pattern 140. In an embodiment, a modified metal layer 190 may be interposed between a lower portion of the second channel pattern 150 and an upper portion of the landing pad LP (e.g., in the Z-axis direction). In an embodiment, the mold portion 130 may include a silicon nitride 131, a silicon oxide 132, and a silicon nitride 133 consecutively stacked in the Z-axis direction from a lower end portion thereof.

According to an embodiment, the second channel pattern 150 may include a semiconductor oxide of the same type as or a different type from the first channel pattern 140. In an embodiment, the semiconductor oxide may include any one or any combination of two or more of IGZO, InₓO, ZnₓO, SnₓO, InₓZn_{y}O, InₓSn_{y}Zn_{z}O, AlₓZn_{y}Sn_{z}O, YbₓGa_{y}Zn_{z}O, and HfₓIn_{y}Zn_{z}O. However, embodiments of the present disclosure are not necessarily limited thereto. For example, in an embodiment the first channel pattern 140 may be formed of an IGZO, and the second channel pattern 150 may be formed of an ITO. The semiconductor oxide may include high proportions of a portion of elements. For example, the IGZO may be a Ga-rich IGZO, and at least one of the first channel pattern 140 or the second channel pattern 150 may be a Ga-rich IGZO.

According to an embodiment, an area of the second channel pattern 150 may be greater than or equal to an area of the top surface of the landing pad LP.

A silicon nitride in an upper end portion of the mold portion 130 may be disposed at a higher level (e.g., in the Z-axis direction) than the first channel pattern 140.

The second channel pattern 150 may extend from the top surface of the landing pad LP to a side surface of the landing pad LP.

In an embodiment, the first channel pattern 140 and the second channel pattern 150 may be formed in an L shape along the outer side surface of the mold portion 130 and the top surface of the landing pad LP.

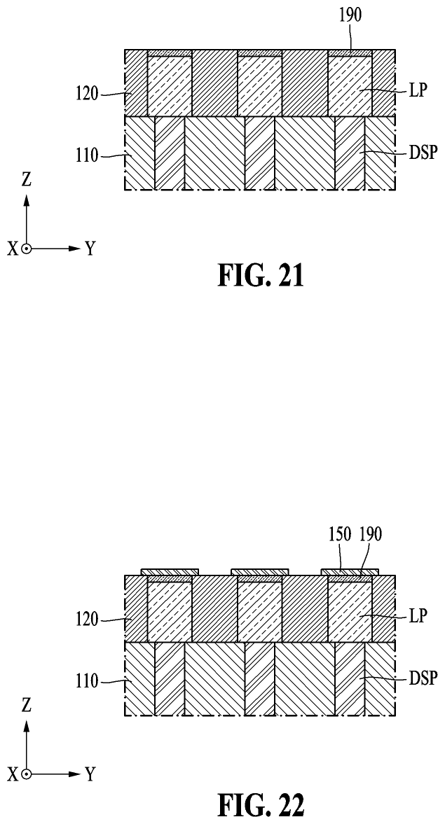

FIGS. 21 to 27 are diagrams to describe a method of manufacturing the semiconductor device 100 of FIG. 20 according to embodiments of the present disclosure.

As described above with reference to FIGS. 4 and 5, the data storage pattern DSP may be disposed on one surface (e.g., a lower surface) of the landing pad LP, and another surface (e.g., an upper surface) of the landing pad LP may be coated with an insulating film IF. The insulating film IF on the landing pad LP may be removed, so that the top surface of the landing pad LP may be exposed.

Referring to FIG. 21, a metal on the upper portion of the landing pad LP may be modified. Since the landing pad LP includes a conductive material, there is a risk of oxidation. To prevent oxidation, nitridation may be performed on the landing pad LP to change properties of the conductive material. By modifying an interface between the second channel pattern 150 and the landing pad LP, the oxidation of the conductive material may be prevented and ions may smoothly move. In an embodiment, a plasma treatment may be used to modify the metal on the landing pad LP, and a heat treatment or a treatment by a deposition may also be possible. However, embodiments of the present disclosure are not necessarily limited thereto.

Referring to FIG. 22, the second channel pattern 150 may be deposited on the landing pad LP including the modified metal. In an embodiment, the second channel pattern 150 may include a semiconductor oxide deposited by a PVD process, a CVD process, or an ALD process. In an embodiment, the semiconductor oxide may include any one or any combination of two or more of IGZO, InₓO, ZnₓO, SnₓO, InₓZn_{y}O, InₓSn_{y}Zn_{z}O, AlₓZn_{y}Sn_{z}O, YbₓGa_{y}Zn_{z}O. However, embodiments of the present disclosure are not necessarily limited thereto.

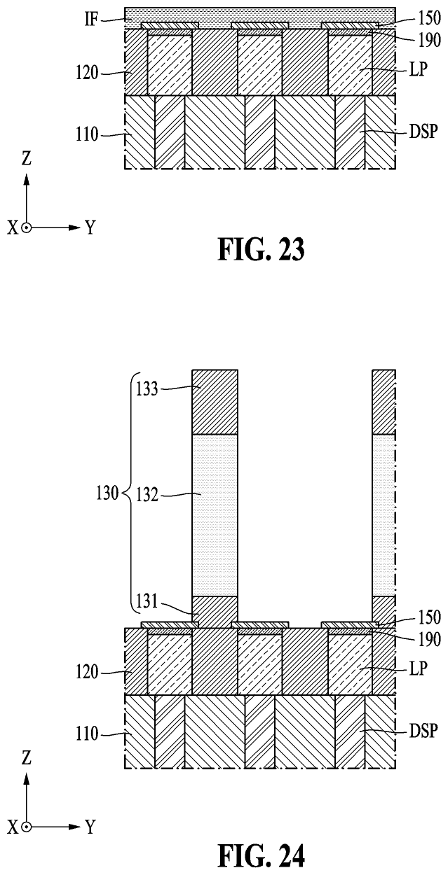

Referring to FIG. 23, the top surface of the landing pad LP on which the second channel pattern 150 is deposited may be coated with an insulating film IF. In an embodiment, when the top surface is coated with the insulating film IF, a planarization process may be performed using a CMP process.

Referring to FIG. 24, an upper portion of the insulating film IF may be exposed. The mold portion 130 may be formed in a vertical direction (e.g., the Z-axis direction) on the exposed upper portion of the first insulating layer 120.

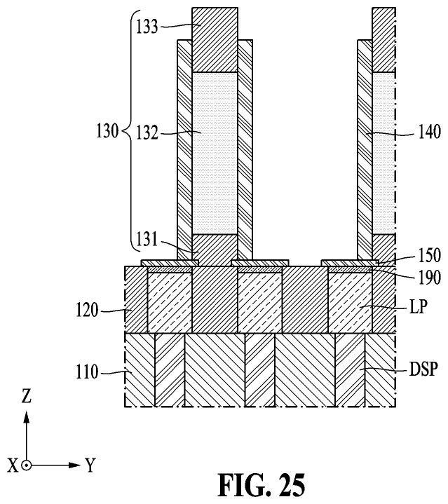

Referring to FIG. 25, in an embodiment the first channel pattern 140 may be formed on (e.g., formed directly thereon) the mold portion 130 by a PVD process, a CVD process, or an ALD process. When the first channel pattern 140 is formed, an upper portion of the first channel pattern 140 may be opened by an etch back process, to form a node.

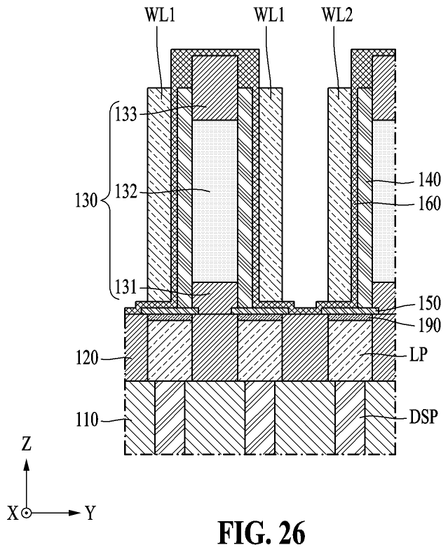

Referring to FIG. 26, the gate insulating pattern 160 may conformally cover the first channel pattern 140. The word lines WL1 and WL2 may be formed on (e.g., formed directly thereon) the gate insulating pattern 160. The word lines WL1 and WL2 may include conductive materials. In an embodiment, chamfering of the word lines WL1 and WL2 may be performed by a wet etch process.

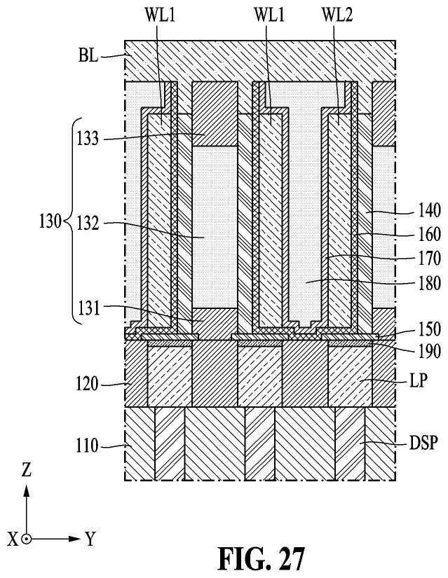

Referring to FIG. 27, the bit line BL may be formed on (e.g., formed directly thereon) the mold portion 130 and the first channel pattern 140.

It should be appreciated that the described embodiments of the present disclosure and the terms used therein are not intended to limit the technological features set forth herein to particular embodiments and embodiments of the present disclosure include various changes, equivalents, or replacements. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order).

Unless otherwise defined, all terms including technical and scientific terms used herein have the same meaning as commonly understood by one of ordinary skill in the art to which embodiments belong. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

When describing embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

It should be noted that if it is described in the specification that one component is “connected,” “coupled” or “joined” to another component, the former may be directly “connected,” “coupled,” and “joined” to the latter or “connected,” “coupled,” and “joined” to the latter via another component.

Effects which can be acquired by the present disclosure are not limited to the effects described above, and other effects that have not been mentioned can be clearly understood by one of ordinary in the art from the present disclosure.

What is claimed is:

1. A semiconductor device comprising:
a bit line extending in a first direction parallel to an upper surface of a substrate;
a first channel pattern connected to the bit line, the first channel pattern extending perpendicular to the upper surface of the substrate;
a gate insulating pattern disposed on the first channel pattern;
a word line disposed on the gate insulating pattern, the word line extending in a second direction that is parallel to the upper surface of the substrate and perpendicular to the first direction;
data storage patterns spaced apart from each other in the first direction and the second direction;
a landing pad disposed on each of the data storage patterns; and
a second channel pattern disposed on the landing pad, the second channel pattern extending from a first end of the first channel pattern in the first direction.

2. The semiconductor device of claim 1, further comprising:
a mold portion extending in the second direction, the mold portion supporting the first channel pattern.

3. The semiconductor device of claim 1, wherein:
the second channel pattern comprises a semiconductor oxide of a same type as the first channel pattern; or
the second channel pattern comprises the semiconductor oxide of a different type from the first channel pattern.

4. The semiconductor device of claim 3, wherein the semiconductor oxide comprises any one or any combination of two or more of IGZO, InₓO, ZnₓO, SnₓO, InₓZn_{y}O, InₓSn_{y}Zn_{z}O, AlₓZn_{y}Sn_{z}O, YbₓGa_{y}Zn_{z}O, and HfₓIn_{y}Zn_{z}O.

5. The semiconductor device of claim 1, wherein the second channel pattern extends from a top surface of the landing pad to a side surface of the landing pad.

6. The semiconductor device of claim 1, wherein a modified metal layer is interposed between a lower portion of the second channel pattern and an upper portion of the landing pad.

7. A method of manufacturing a semiconductor device, the method comprising:
preparing a landing pad, wherein a data storage pattern disposed on a first surface of the
landing pad and an insulating film coated on a second surface of the landing pad opposite
to the first surface;
exposing an upper portion of the landing pad by removing the insulating film from the landing pad;
forming a second channel pattern on the exposed upper portion of the landing pad;
coating the second channel pattern with the insulating film and performing a planarization process thereon;
forming a mold portion on a first insulating layer, disposed between the landing pad and a second landing pad, the mold portion extending in a direction perpendicular to the first insulating layer;
forming a first channel pattern on an outer side surface of the mold portion and opening an upper portion of the first channel pattern;
forming a gate insulating pattern on a side surface of the first channel pattern;
forming a word line on a side surface of the gate insulating pattern; and
forming a bit line on the first channel pattern.

8. The method of claim 7, further comprising:
covering at least an entire top surface of the landing pad by the second channel pattern.

9. The method of claim 7, further comprising:
forming a recess by removing a portion of a side surface of the first insulating layer in direct contact with a side surface of the landing pad.

10. The method of claim 7, further comprising:
modifying a metal that is disposed on the upper portion of the landing pad.

11. The method of claim 7, wherein:
the first channel pattern and the second channel pattern comprise semiconductor oxides of a same type as each other; or
the first channel pattern and the second channel pattern comprise semiconductor oxides of a different type from each other.

12. The method of claim 11, wherein the semiconductor oxides comprise any one or any combination of IGZO, InₓO, ZnₓO, SnₓO, InₓZn_{y}O, InₓSn_{y}Zn_{z}O, AlₓZn_{y}Sn_{z}O, YbₓGa_{y}Zn_{z}O, and HfₓIn_{y}Zn_{z}O.

13. The method of claim 7, wherein the mold portion protrudes further upward than a top surface of the first channel pattern.

14. A semiconductor device comprising:
a landing pad disposed in a first insulating layer;
a data storage pattern disposed under the landing pad;
a mold portion extending in a vertical direction on the first insulating layer;
a first channel pattern disposed on an outer side surface of the mold portion and extending in a direction perpendicular to the landing pad;
a second channel pattern extending horizontally on a top surface of the landing pad;
a gate insulating pattern disposed on a side surface of the first channel pattern;
a word line disposed on a side surface of the gate insulating pattern; and
a bit line disposed on the first channel pattern, the bit line extending in a direction perpendicular to the word line,
wherein a silicon nitride in an upper end portion of the mold portion protrudes further upward than a top surface of the first channel pattern.

15. The semiconductor device of claim 14, wherein:
the first channel pattern and the second channel pattern comprise semiconductor oxides of a same type as each other; or
the first channel pattern and the second channel pattern comprise semiconductor oxides of a different type from each other.

16. The semiconductor device of claim 15, wherein the semiconductor oxides comprise any one or any combination of IGZO, InₓO, ZnₓO, SnₓO, InₓZn_{y}O, InₓSn_{y}Zn_{z}O, AlₓZn_{y}Sn_{z}O, YbₓGa_{y}Zn_{z}O, and HfₓIn_{y}Zn_{z}O.

17. The semiconductor device of claim 14, wherein the second channel pattern extends from the top surface of the landing pad to a side surface of the landing pad.

18. The semiconductor device of claim 14, wherein a modified metal layer is interposed between a lower portion of the second channel pattern and an upper portion of the landing pad.

19. The semiconductor device of claim 14, wherein an area of the second channel pattern is greater than or equal to an area of the top surface of the landing pad.

20. The semiconductor device of claim 14, wherein the first channel pattern and the second channel pattern are formed in an L-shape with respect to the outer side surface of the mold portion and the top surface of the landing pad.
